(19) United States
(12) Patent Application Publication
(10) Pub. No.: US 2025/0069848 A1
(43) Pub. Date: Feb. 27, 2025

(54) CHARGED PARTICLE BEAM APPARATUS AND CONTROL METHOD THEREOF

(71) Applicant: Kioxia Corporation, Tokyo (JP)

(72) Inventor: Kazuya HATANO, Nagoya Aichi (JP)

(21) Appl. No.: 18/791,075

(22) Filed: Jul. 31, 2024

(30) Foreign Application Priority Data
Aug. 25, 2023 (JP) 2023-137578

(51) Int. Cl. H01J 37/26; H01J 37/22; H01J 37/244; H01J 37/28

(52) U.S. Cl. CPC H01J 37/265; H01J 37/222; H01J 37/244; H01J 37/28; H01J 2237/20214; H01J 2237/31749

(57) ABSTRACT

A charged particle beam apparatus includes a holding structure for a sample, a first irradiation device configured to process the sample to have first and second surfaces separated by a first distance, by irradiating the sample with first charged particles from a second direction, a second irradiation device configured to irradiate the first and second surfaces with second charged particles from the first direction, a detector configured to detect third charged particles from the first and second surfaces, an image processing circuit configured to generate images of the first and second surfaces based on the detected third charged particles, and a processor configured to calculate an inclination angle of a reference plane with respect to the first direction based on a deviation amount in the second direction of the reference plane between the images, and the first distance, and generate a control signal for rotating the holding structure.

### CROSS-REFERENCE TO RELATED APPLICATION(S)

This application is based upon and claims the benefit of priority from Japanese Patent Application No. 2023-137578, filed Aug. 25, 2023, the entire contents of which are incorporated herein by reference.

### FIELD

Embodiments described herein relate generally to a charged particle beam apparatus and a control method thereof.

### BACKGROUND

With the multilayering of the semiconductor element structure, an aspect ratio in processing of the structure has increased. When observing a sample having a high aspect ratio with a focused ion beam (FIB)—scanning electron microscope (SEM) device, the sample may be inclined from a desired posture.

### DESCRIPTION OF THE DRAWINGS

FIG. 1 is a diagram showing a configuration example of a charged particle beam apparatus according to a first embodiment.

FIG. 2 is a diagram showing a state in which an FIB irradiation unit and an EB irradiation unit are irradiating a sample with an ion beam and an electron beam.

FIG. 3A is a plan view showing a state of processing of a sample.

FIG. 3B is a cross-sectional view taken along the line B-B of FIG. 3A.

FIG. 3C is a cross-sectional view taken along the line C-C of FIG. 3A.

FIG. 4A is a plan view showing a state of processing of the sample.

FIG. 4B is a cross-sectional view taken along the line B-B of FIG. 4A.

FIG. 4C is a cross-sectional view taken along the line C-C of FIG. 4A.

FIG. 5A is a plan view showing a state of processing of a sample.

FIG. 5B is a cross-sectional view taken along the line B-B of FIG. 5A.

FIG. 5C is a cross-sectional view taken along the line C-C of FIG. 5A.

FIG. 6 is a diagram showing a relationship between a distance, a deviation amount, and an inclination angle.

FIG. 7 is a flowchart showing an example of a control method of the charged particle beam apparatus according to the first embodiment.

FIG. 8A is a diagram showing a state of processing of a sample according to a second embodiment.

FIG. 8B is a cross-sectional view taken along the line B-B of FIG. 8A.

FIG. 8C is a cross-sectional view taken along the line C-C of FIG. 8A.

FIG. 9A is a diagram showing a state of processing of a sample according to the second embodiment.

FIG. 9B is a cross-sectional view taken along the line B-B of FIG. 9A.

FIG. 9C is a cross-sectional view taken along the line C-C of FIG. 9A.

FIG. 10 is a flowchart showing an example of a control method of the charged particle beam apparatus according to the second embodiment.

FIG. 11A is a diagram showing a state of processing of a sample according to a third embodiment.

FIG. 11B is a cross-sectional view taken along the line B-B of FIG. 11A.

FIG. 11C is a cross-sectional view taken along the line C-C of FIG. 11A.

FIG. 12A is a diagram showing a state of processing of a sample according to the third embodiment.

FIG. 12B is a cross-sectional view taken along the line B-B of FIG. 12A.

FIG. 12C is a cross-sectional view taken along the line C-C of FIG. 12A.

FIG. 13A is a diagram showing a state of processing of a sample according to the third embodiment.

FIG. 13B is a cross-sectional view taken along the line B-B of FIG. 13A.

FIG. 13C is a cross-sectional view taken along the line C-C of FIG. 13A.

### DETAILED DESCRIPTION

Embodiments provide a charged particle beam apparatus and a control method thereof, with which an inclination of a sample can be automatically corrected.

In general, according to one embodiment, the charged particle beam apparatus according to the present embodiment includes a holding structure for a sample having a reference plane, the holding structure being rotatable to change an angle of the sample with respect to at least a first direction. A first irradiation device is configured to process the sample to have a first surface intersecting the reference plane and a second surface separated from the first surface in the first direction by a first distance by irradiating the sample with first charged particles from a second direction. A second irradiation device is configured to irradiate the first surface and the second surface with second charged particles from the first direction. A detector is configured to detect third charged particles from the first surface and the second surface that have been irradiated with the second charged particles. An image processing circuit is configured to generate a first image of the first surface and a second image of the second surface based on the detected third charged particles, respectively. A processor is configured to calculate an inclination angle of the reference plane with respect to the first direction based on (i) a first deviation amount in the second direction of the reference plane in the first image and the second image, and (ii) the first distance, and generate a control signal for rotating the holding structure based on the inclination angle.

Hereinafter, embodiments of the present disclosure will be described with reference to the drawings. The disclosed embodiments do not limit the scope of the present disclosure. The drawings are schematic or conceptual. In the specification and drawings, the same elements are denoted by the same reference numerals or symbols.

### First Embodiment

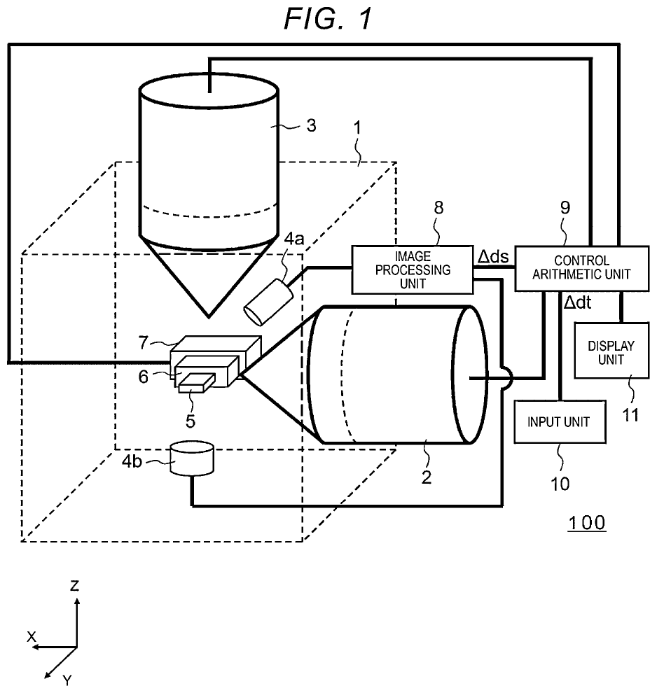

FIG. 1 is a diagram showing a configuration example of a charged particle beam apparatus according to a first embodiment. The charged particle beam apparatus 100 is an FIB-SEM device that irradiates a sample 5 processed by the FIB with an electron beam to detect secondary electrons generated from the sample 5, thereby obtaining an image of the sample 5.

The charged particle beam apparatus 100 includes a chamber 1, an FIB irradiation unit 2, an electron beam (EB) irradiation unit 3, a secondary electron detector 4a, a transmission electron detector 4b, a holding unit 6, a driving unit 7, an image processing unit 8, a control arithmetic unit 9, an input unit 10, and a display unit 11.

The chamber 1 accommodates the sample 5. The inside of the chamber 1 is depressurized by a vacuum pump (not shown).

The FIB irradiation unit 2 irradiates the sample 5 with a focused ion beam (FIB) from an X direction to process the sample 5. The FIB irradiation unit 2 is an FIB irradiation device that includes an FIB generator with an ion beam source that the FIB generator focuses to produce the FIB.

The EB irradiation unit 3 irradiates the sample 5 with an electron beam (EB) from a Z direction. The EB irradiation unit 3 is an EB irradiation device that includes an EB generator with an electron beam source that produces the EB. The Z direction and the X direction are substantially orthogonal to each other. That is, the irradiation direction of the focused ion beam of the FIB irradiation unit 2 is orthogonal to the irradiation direction of the electron beam of the EB irradiation unit 3. Therefore, the charged particle beam apparatus 100 may be referred to as an orthogonal charged particle beam apparatus.

The secondary electron detector 4a detects electrons generated from the sample 5 when the sample 5 is irradiated with the electron beam. These electrons are referred to as secondary electrons.

The transmission electron detector 4b detects electrons transmitted through the sample 5. These electrons are referred to as transmission electrons.

The holding unit 6 is a physical structure that holds the sample 5. The holding unit 6 includes a holding face to which the sample 5 is bonded. The holding unit 6 is movably held by the driving unit 7. More specifically, the holding unit 6 is rotated by the driving unit 7 to change the angle of the sample 5 with respect to the X direction or the Z direction.

The driving unit 7 is a physical mechanism that moves or rotates the holding unit 6 under the control of the control arithmetic unit 9. The driving unit 7 has a shaft portion, and the shaft portion can be rotated by a motor, for example. The driving unit 7 changes an incidence angle of the ion beam or the electron beam with respect to the sample 5, for example, by moving or rotating the holding unit 6.

The image processing unit 8 is a circuit (e.g., application-specific integrated circuit or a circuit including a programmed processor and memory) that generates an image of the sample 5 based on the secondary electrons detected by the secondary electron detector 4a. In addition, the image processing unit 8 monitors the transmission electron amount detected by the transmission electron detector 4b.

The control arithmetic unit 9 is a processor, e.g., a central processing unit (CPU) or a microprocessor unit (MPU), that processes the image of the sample 5 generated by the image processing unit 8 and controls the driving unit 7 in order to correct the inclination of the sample 5. The control arithmetic unit 9 controls the FIB irradiation unit 2, the EB irradiation unit 3, and the like. The control arithmetic unit 9 displays the image of the sample 5 on the display unit 11.

The input unit 10 is an input device capable of inputting various types of information from the outside, and transmits the input information to the control arithmetic unit 9. The input unit 10 may be, for example, a keyboard.

The display unit 11 is a display device that displays an image or the like from the control arithmetic unit 9. The input unit 10 and the display unit 11 may be integrated in one device, e.g., a touch panel display.

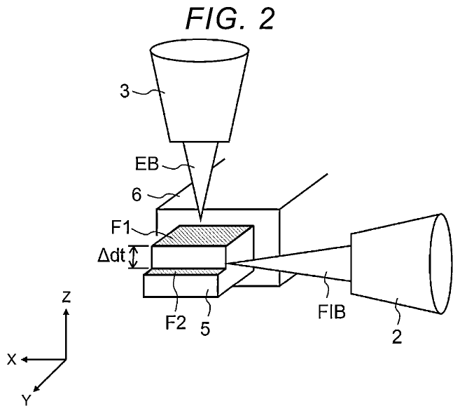

FIG. 2 is a diagram showing a state in which the FIB irradiation unit 2 and the EB irradiation unit 3 are irradiating the sample 5 with an ion beam and an electron beam.

The FIB irradiation unit 2 cuts the sample 5 by irradiating the sample 5 with the ion beam in the X direction. As a result, the sample 5 can be processed to have the first surface F1 and the second surface F2 that are substantially parallel to each other in the X-Y plane. The second surface F2 is a surface separated from the first surface F1 in the −Z direction by a distance Δdt. The first and second surfaces F1 and F2 are planes that are substantially parallel to each other.

The EB irradiation unit 3 irradiates the first and second surfaces F1 and F2 of the sample 5 with an electron beam from the Z direction. The secondary electron detector 4a detects secondary electrons generated when the sample 5 is irradiated with the electron beam. The image processing unit 8 generates the image of each of the first and second surfaces F1 and F2 of the sample 5 based on the secondary electron amount (in particular, intensity of the secondary electrons) detected by the secondary electron detector 4a.

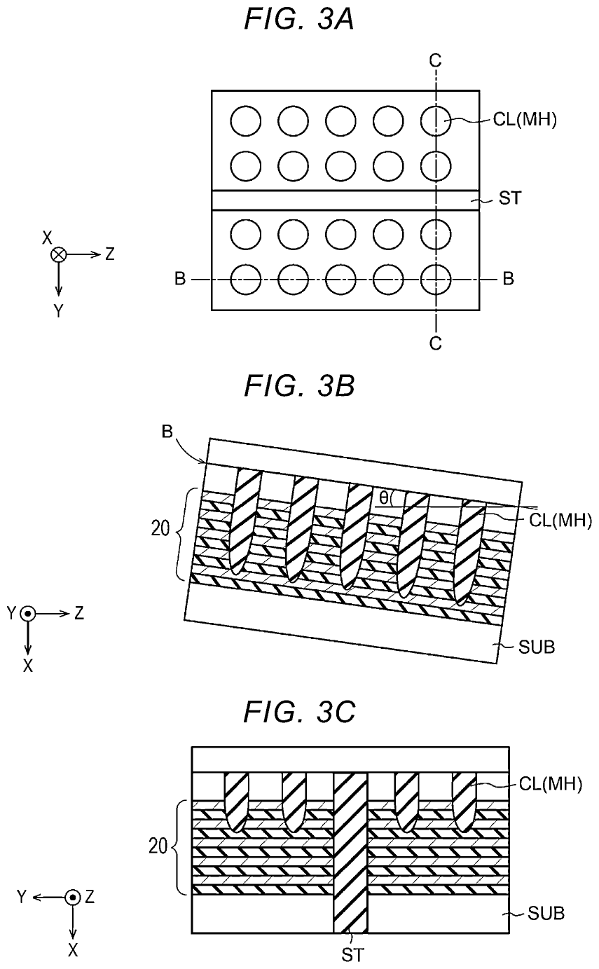

FIGS. 3A to 5C are diagrams showing a state of processing of sample 5. FIGS. 3A, 4A, and 5A are plan views of the sample 5. FIGS. 3B, 4B, and 5B are cross-sectional views taken along the line B-B in FIGS. 3A, 4A, and 5A, respectively. FIGS. 3C, 4C, and 5C are cross-sectional views taken along the line C-C in FIGS. 3A, 4A, and 5A, respectively.

As shown in FIGS. 3A to 3C, the sample 5 includes, for example, a stacked body 20 in which a plurality of electrode films and a plurality of insulating films are alternately stacked along the Z direction. The stacked body 20 constitutes a memory cell array. The memory cell array is a three-dimensional memory cell array in which memory cells are three-dimensionally arranged. A substrate SUB is, for example, a semiconductor substrate such as a silicon substrate.

Columnar bodies CL are provided in each of the plurality of memory holes MH in the stacked body 20. The columnar body CL extends in a stacking direction (X direction) of the stacked body so as to penetrate the stacked body. The description of the internal structure of the columnar body CL is omitted. In the present embodiment, the columnar body CL is formed in one stage. However, where the columnar body CL has a high aspect ratio, the columnar body CL may be formed in two stages in the X direction.

In addition, a slit ST is provided in the stacked body 20. The slit ST extends in the Z direction and penetrates the stacked body 20 in the stacking direction (X direction) of the stacked body 20. The slit ST is filled with an insulating film such as a silicon oxide film, and the insulating film has a plate shape. The slit ST electrically separates the electrode films of the stacked body 20. Alternatively, an insulating film such as a silicon oxide film may be coated on the inner wall of the slit ST, and a conductive material may be embedded in the slit ST to be sandwiched by the insulating film. In this case, the conductive material also functions as a source wiring line that reaches a source layer under the stacked body 20.

With reference to FIG. 3B, it can be seen that the sample 5 is inclined at an inclination angle θ with respect to the Z direction. The inclination is an inclination of the sample 5 in the irradiation direction (Z direction) of the electron beam from the EB irradiation unit 3. The inclination of the sample 5 is an inclination of an interface (reference plane) B between the material layers stacked in the sample 5. For example, the interface B is an interface between any two layers provided in the sample 5. Specifically, for example, the interface B may be an interface between two insulating films having different compositions, which are formed on the stacked body 20, or an interface between the conductive film (for example, the metal film) and the insulating film. In addition, the interface B may be an interface between the surface of the semiconductor substrate and the interlayer insulating film thereon, or an interface between the stacked body 20 and the interlayer insulating film deposited thereon. The inclination of the sample 5 is present because of the manner of holding the sample 5 by the holding unit 6. In other words, when the holding unit 6 holds the sample 5, the inclination of the sample 5 may occur. In order to automatically correct the inclination of the sample 5 to the target value (for example, to bring the inclination angle θ close to zero), the charged particle beam apparatus 100 processes the sample 5 and performs the calculation as follows.

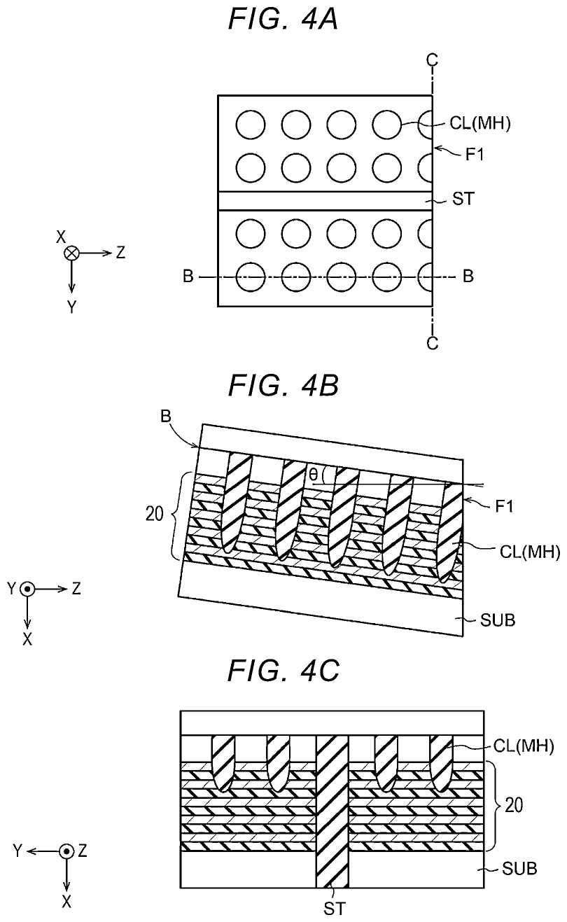

As shown in FIGS. 4A to 4C, the FIB irradiation unit 2 irradiates a part of the sample 5 with an ion beam to process the sample 5. The FIB irradiation unit 2 cuts the sample 5 by irradiating the sample 5 with the ion beam from the X direction and moving the emitted ion beam in at least a Y direction. Alternatively, the FIB irradiation unit 2 may cut the sample 5 by irradiating the sample 5 with an ion beam from the X direction and moving the emitted ion beam in the Y direction and the Z direction. As a result, as shown in FIG. 4B, the sample 5 is processed to have a cut surface (first surface F1) that is substantially parallel to the X-Y plane.

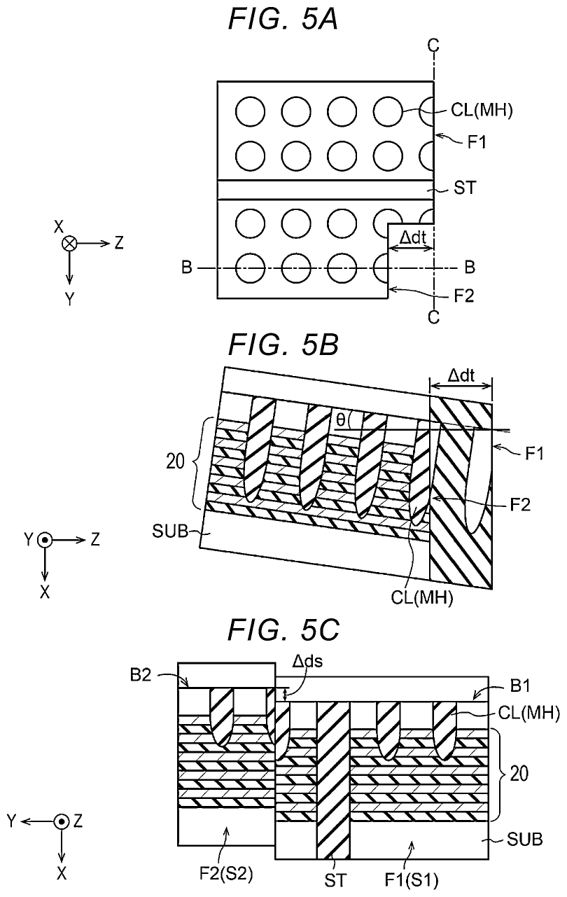

Next, as shown in FIGS. 5A to 5C, the FIB irradiation unit 2 irradiates a part of the sample 5 with the ion beam to process the sample 5. The FIB irradiation unit 2 irradiates the sample 5 with an ion beam from the X direction and cuts a part of the sample 5 in the Y direction by moving the emitted ion beam in at least the Y direction. Alternatively, the FIB irradiation unit 2 may cut a part of the sample 5 by irradiating the sample 5 with the ion beam from the X direction and moving the emitted ion beam in the Y direction and the Z direction. In this case, as shown in FIG. 5A, the ion beam cuts a part of the first surface F1 of the sample 5 to process the sample 5 such that the second surface F2 has a step shape. As a result, as shown in FIG. 5B, the sample 5 is further processed to have a second surface F2 that is substantially parallel to the X-Y plane. The second surface F2 is substantially parallel to the first surface F1 and is a surface of the sample 5 that is separated from the first surface F1 by a distance Δdt in the Z direction.

Here, as shown in FIG. 5B, the sample 5 is inclined at an inclination angle θ with respect to the Z direction. Therefore, as shown in FIG. 5C, the first image S1 of the first surface F1 and the second image S2 of the second surface F2 obtained by the irradiation with the electron beam from the Z direction by the EB irradiation unit 3 are deviated from each other in the X direction (height direction). That is, since the sample 5 is inclined in the Z direction in a plan view from the Z direction and the depths of the first surface F1 and the second surface F2 are different from each other, the position of the structure of the sample 5 on the first surface F1 and the position of the structure of the sample 5 on the second surface F2 are deviated from each other in the X direction (height direction).

When the inclination angle θ is zero, the first image of the first surface F1 and the second image of the second surface F2 in FIG. 5C should not be deviated from each other in the X direction, and the position of the structure of the sample 5 in the first surface F1 and the position (height) of the structure of the sample 5 in the second surface F2 should substantially match in the X direction.

However, since the sample 5 is inclined at the inclination angle θ with respect to the Z direction, the first image S1 of the first surface F1 and the second image S2 of the second surface F2 are deviated from each other in the X direction (height direction). It is assumed that an interface B1 between the two interlayer insulating films having different compositions, which are formed on the stacked body 20 in the first image S1, and an interface B2 between the two interlayer insulating films having different compositions, which are formed on the stacked body 20 in the second image S2, are deviated from each other in the X direction by a deviation amount Δds. The interfaces B1 and B2 may be, for example, any interface between two layers provided in the sample 5. Specifically, for example, the interfaces B1 and B2 may be an interface between two insulating films having different compositions, which are formed on the stacked body 20, or an interface between the conductive film (for example, the metal film) and the insulating film. In addition, the interfaces B1 and B2 may be an interface between the surface of the semiconductor substrate and the interlayer insulating film thereon, or an interface between the stacked body 20 and the interlayer insulating film deposited thereon.

The control arithmetic unit 9 according to the present embodiment calculates the inclination angles θ of the interfaces B1 and B2 with respect to the Z direction based on the distance Δdt between the first surface F1 and the second surface F2 and the deviation amount Δds in the X direction between the interface B1 of the first surface F1 and the interface B2 of the second surface F2 by using the principle of the triangulation. A value input from the outside by the input unit 10 may be used as the distance Δdt. Alternatively, the image processing unit 8 and the control arithmetic unit 9 may measure the distance Δdt using a scanning ion microscope (SIM) image obtained when the FIB irradiation unit 2 emits the ion beam.

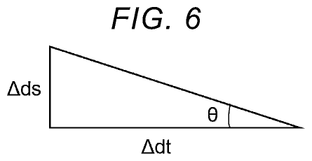

FIG. 6 is a diagram showing a relationship between the distance Δdt, the deviation amount Δds, and the inclination angle θ. In this case, the control arithmetic unit 9 calculates the inclination angles θ of the interfaces B1 and B2 with respect to the Z direction by using Expression 1.

$$θ = {tan}^{- 1} ( Δ ds / Δ dt ) \qquad ( Expression 1 )$$

The control arithmetic unit 9 drives the driving unit 7 to bring the inclination angle θ close to a target value (for example, zero), and performs feedback control of the inclination of the holding unit 6. As a result, the inclination of the sample 5 can be automatically corrected.

As described above, the charged particle beam apparatus 100 according to the present embodiment can automatically correct the inclination of the sample 5. By correcting the inclination of the sample 5, the FIB irradiation unit 2 may cut the sample 5 with the ion beam in a substantially orthogonal direction with respect to the interfaces B1 and B2. As a result, it is possible to know the accurate structure of the sample 5 from the image obtained by irradiating the sample 5 with the electron beam by the EB irradiation unit 3.

When acquiring the first image S1 of the first surface F1 and the second image S2 of the second surface F2 of the sample 5, the EB irradiation unit 3 may emit the electron beam at the same focus. However, when the distance Δdt between the first surface F1 and the second surface F2 is large, the focus of the first surface F1 and the second surface F2 exceeds a range of the depth of focus of the electron beam, therefore, there is a risk that the focus of the first image S1 or the second image S2 is deviated when the focus of the electron beam is the same. In this case, the detection accuracy of the deviation amount Δds is deteriorated.

Therefore, when acquiring the first image S1 of the first surface F1 of the sample 5, the EB irradiation unit 3 irradiates the first surface F1 with the electron beam while focusing on the first surface F1. When acquiring the second image S2 of the second surface F2, the EB irradiation unit 3 irradiates the second surface F2 with the electron beam while focusing on the second surface F2. The secondary electron detector 4a separately detects the first surface F1 and the second surface F2 by focusing the electron beam on each of the first surface F1 and the second surface F2. When the first surface F1 and the second surface F2 are detected by focusing the electron beam on each of the first surface F1 and the second surface F2, the position of the sample 5 and an optical condition of the electron beam are not changed. The image processing unit 8 combines the first image S1 and the second image S2 separately obtained by changing the focus of the electron beam in this way to generate a composite image. The first image S1 and the second image S2 are combined by combining outer peripheral portions of the images. As a result, for example, the image shown in FIG. 5C is obtained. In the composite image, the deviation of the focus is prevented. Therefore, the image processing unit 8 may accurately measure the deviation amount Δds between the interfaces B1 and B2 based on the composite image.

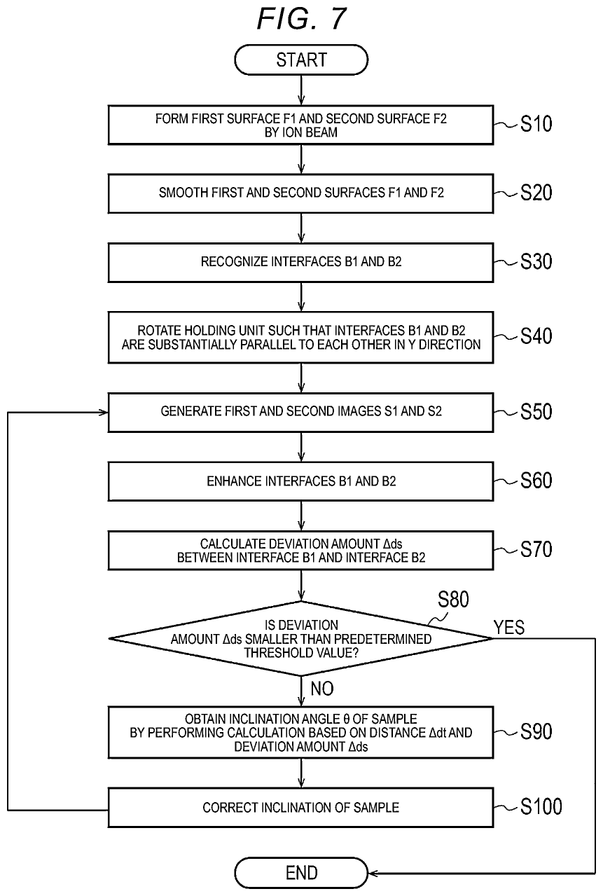

FIG. 7 is a flowchart showing an example of a control method of the charged particle beam apparatus according to the first embodiment.

First, the sample 5 is attached to the holding unit 6 and disposed in the chamber 1.

The FIB irradiation unit 2 irradiates the sample 5 with the ion beam to process the sample 5 into a step shape to form the first surface F1 and the second surface F2 (S10). The FIB irradiation unit 2 cuts the sample 5 by irradiating the sample 5 with the ion beam from the X direction and moving the emitted ion beam in at least a Y direction. Alternatively, the FIB irradiation unit 2 may cut the sample 5 by irradiating the sample 5 with an ion beam from the X direction and moving the emitted ion beam in the Y direction and the Z direction. When forming the first surface F1, the sample 5 may be cut so that the first surface F1 is flat with respect to the X-Y plane, and thus a recess amount of the sample 5 in the Z direction may be small. On the other hand, when forming the second surface F2, it is necessary to increase the distance Δdt between the first surface F1 and the second surface F2 to some extent in order to increase the deviation amount Δds. Therefore, the recess amount (Δdt) of the second surface F2 with respect to the first surface F1 in the Z direction is preferably larger than the recess amount of the sample 5 in the Z direction on the first surface F1.

Next, the first and second surfaces F1 and F2 are thinly shaved with an ion beam to smooth the first and second surfaces F1 and F2, which are imaging surfaces of the sample 5 (S20).

Next, the image processing unit 8 generates the images of the first and second surfaces F1 and F2, and recognizes the interfaces B1 and B2 of the sample 5 (S30). Further, the image processing unit 8 may emphasize the interfaces B1 and B2.

Next, the control arithmetic unit 9 controls the driving unit 7 to rotate the holding unit 6 such that the interfaces B1 and B2 are substantially parallel to each other in the Y direction (S40).

Next, the EB irradiation unit 3 irradiates the first and second surfaces F1 and F2 of the sample 5 with the electron beam, and the detection unit 4 detects the secondary electrons from the sample 5. The image processing unit 8 generates the first and second images S1 and S2 from the detected secondary electrons (S50). The EB irradiation unit 3 may simultaneously irradiate the first and second surfaces F1 and F2 of the sample 5 with the electron beam, so that the detection unit 4 may detect the secondary electrons from the sample 5 at once. In this case, the image processing unit 8 may simultaneously obtain the first and second images S1 and S2 with one irradiation of the electron beam. On the other hand, the first and second surfaces F1 and F2 may be respectively irradiated with the electron beam by changing the focus of the electron beam. In this case, the image processing unit 8 generates the first and second images S1 and S2 from the secondary electrons separately detected by the detection unit 4, respectively, and then combines the first and second images S1 and S2 to obtain a composite image. The first and second surfaces F1 and F2 are irradiated with an electron beam from the EB irradiation unit 3 by adapting the focus to each of the first and second surfaces F1 and F2. As a result, the detection unit 4 and the image processing unit 8 can capture the first and second images S1 and S2 at different timings, respectively. Therefore, the first and second images S1 and S2 are images in which the first and second surfaces F1 and F2 are in focus, respectively. That is, the composite image is an image in which the first and second surfaces F1 and F2 are in focus.

Further, the image processing unit 8 enhances the interfaces B1 and B2 by the image processing of the first and second images S1 and S2 or the composite image (S60). For example, the interface B1 is enhanced by using the first image S1. The image processing unit 8 performs contrast enhancement processing on the first image S1. First, the area surrounding the interface B1 is extracted from the first image S1 to generate an extracted image, and then a luminance histogram is created for each pixel using the extracted image. Finally, the obtained histograms are averaged to enhance the contrast of the interface B1. The interface B2 may also be enhanced in the same manner as the interface B1.

Next, the control arithmetic unit 9 calculates the deviation amount Δds between the interface B1 and the interface B2 from the first and second images S1 and S2 or the composite image (S70).

The control arithmetic unit 9 compares the deviation amount Δds with a predetermined threshold value (S80). When the deviation amount Δds is equal to or larger than a predetermined threshold value (NO in S80), the control arithmetic unit 9 obtains the inclination angle θ of the sample 5 by performing calculation of Expression 1 from the distance Δdt between the first surface F1 and the second surface F2, which is input in advance, and the deviation amount Δds (S90).

Next, in order to bring the inclination angle θ close to zero, the control arithmetic unit 9 performs feedback control of the driving unit 7 and the holding unit 6 to correct the inclination of the sample 5 in the Z direction (S100).

The control arithmetic unit 9 repeats steps S50 to S100 after the inclination of the sample 5 is corrected. That is, the control arithmetic unit 9 repeats the calculation of the inclination angle θ and the control of the holding unit 6 until the deviation amount Δds becomes smaller than a predetermined threshold value.

When the deviation amount Δds is smaller than a predetermined threshold value (YES in S80), the control arithmetic unit 9 ends the adjustment of the inclination angle θ.

As described above, in the charged particle beam apparatus 100 according to the present embodiment, the inclination of the sample 5 in the Z direction can be automatically corrected based on the deviation amounts Δds of the interfaces B1 and B2 in the images S1 and S2 of each of the first surface F1 and the second surface F2 of the sample 5. By correcting the inclination of the sample 5 in the Z direction, the FIB irradiation unit 2 may cut the sample 5 with the ion beam in a substantially orthogonal direction with respect to the interfaces B1 and B2. As a result, it is possible to know the accurate structure of the sample 5 from the image obtained by irradiating the sample 5 with the electron beam by the EB irradiation unit 3.

When the distance Δdt between the first and second surfaces F1 and F2 is small, the EB irradiation unit 3 may substantially adapt the focus of the electron beam to both the first and second surfaces F1 and F2 at once. In this case, the detection unit 4 and the image processing unit 8 may image the first and second surfaces F1 and F2 at once and acquire the first and second images S1 and S2 at once. However, when the distance Δdt between the first and second surfaces F1 and F2 is too small, the deviation amount Δds of the interfaces B1 and B2 due to the inclination angle θ of the sample 5 is small. In this case, the calculation accuracy of the inclination angle θ in the control arithmetic unit 9 is lower than when the distance Δdt between the first and second surfaces F1 and F2 is large.

On the other hand, when the distance Δdt between the first and second surfaces F1 and F2 is large, the deviation amount Δds of the interfaces B1 and B2 is large. Therefore, the calculation accuracy of the inclination angle θ in the control arithmetic unit 9 is relatively high. However, it is difficult for the EB irradiation unit 3 to focus the electron beam on both the first and second surfaces F1 and F2 at once. Therefore, in this case, the image processing unit 8 needs to generate the composite image by combining the first and second surfaces F1 and F2 obtained by separately imaging each of the first and second surfaces F1 and F2. For example, the distance Δdt is preferably 1 μm to 100 μm.

In addition, when the sample 5 is shaved from the first surface F1 to form the second surface F2, there is a risk that the electron beam is transmitted through the sample 5 in a case where the thickness of the sample 5 in the Y direction to be left in the region of the second surface F2 is too thin. In this case, the secondary electrons detected by the detection unit 4 are reduced. Therefore, the thickness of the sample 5 in the Y direction to be left in the region of the second surface F2 is preferably a thickness equal to or greater than a thickness at which the electron beam does not transmit.

### Second Embodiment

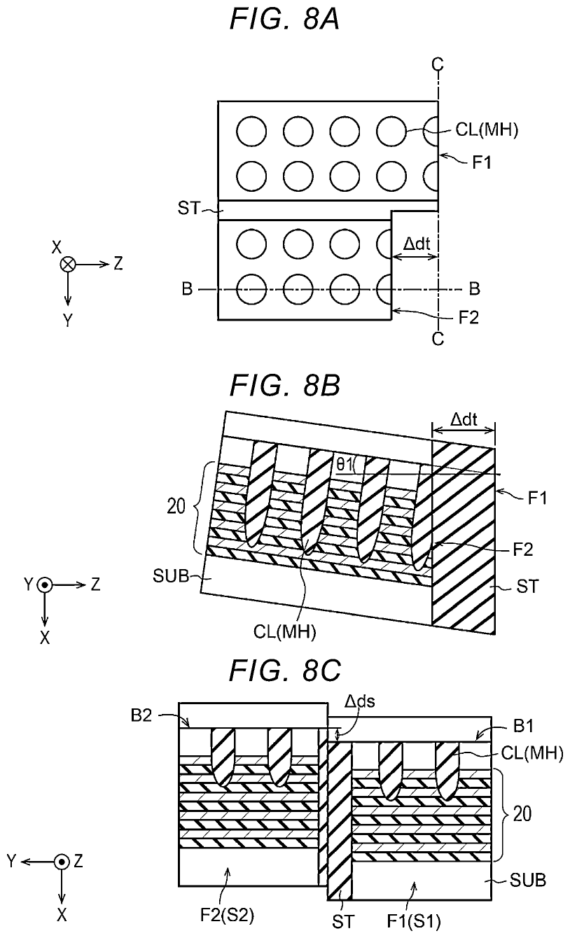

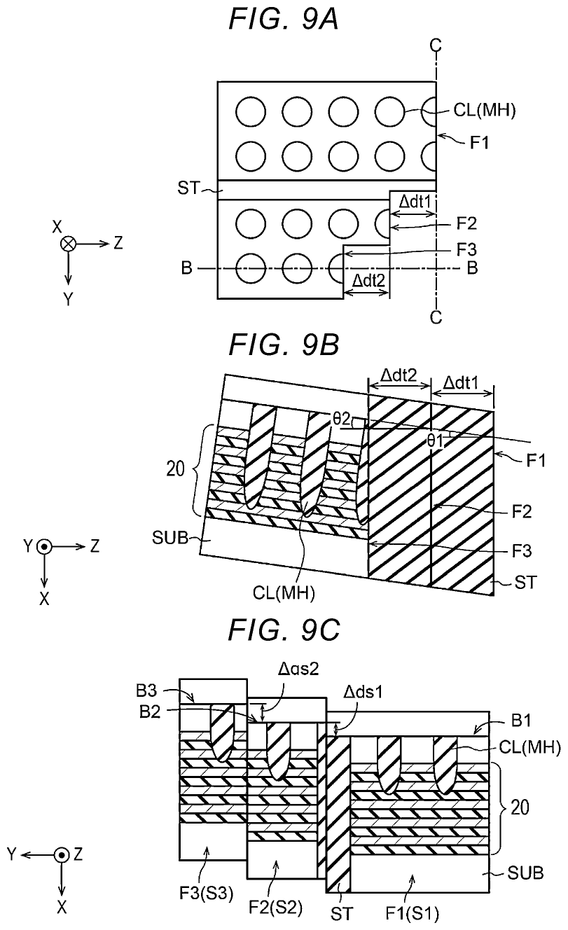

FIGS. 8A to 9C are diagrams showing a state of processing of the sample 5 according to the second embodiment. FIGS. 8A and 9A are plan views of the sample 5. FIGS. 8B and 9B are cross-sectional views taken along the line B-B of FIGS. 8A and 9A, respectively. FIGS. 8C and 9C are cross-sectional views taken along the line C-C of FIGS. 8A and 9A, respectively.

In the second embodiment, the sample 5 has a third surface F3 separated from the first and second surfaces F1 and F2 in the Z direction. The control arithmetic unit 9 calculates the first inclination angle θ1 from Expression 1 based on the first deviation amount Δds1 of the interfaces B1 and B2 in the first image S1 and the second image S2 and the first distance Δdt1 from the first surface F1 to the second surface F2, in the same manner as in the first embodiment.

Further, the control arithmetic unit 9 acquires a third image S3 of the third surface F3 separated from the first and second surfaces F1 and F2 in the Z direction, and measures the second deviation amount Δds2 of each of the interfaces B2 and B3 in the second image S2 and the third image S3. The control arithmetic unit 9 calculates the second inclination angle θ2 from Expression 1 based on the second deviation amount Δds2 and the second distance Δdt2 from the second surface F2 to the third surface F3.

The control arithmetic unit 9 calculates an average value θa of the inclination angles θ1 and θ2. The control arithmetic unit 9 controls the driving unit 7 and the holding unit 6 such that the average value θa is brought close to zero.

The configuration of the second embodiment may be the same as that of the first embodiment.

According to the second embodiment, a plurality of first and second inclination angles θ1 and θ2 are calculated by forming a plurality of steps on the sample 5 and using the first to third surfaces F1 to F3 and the first to third images S1 to S3 due to each of the steps. In this manner, in the second embodiment, the inclination angle of the sample 5 with respect to the Z direction is calculated by the average of the plurality of inclination angles θ1 and θ2, so that the inclination angle can be calculated with higher accuracy.

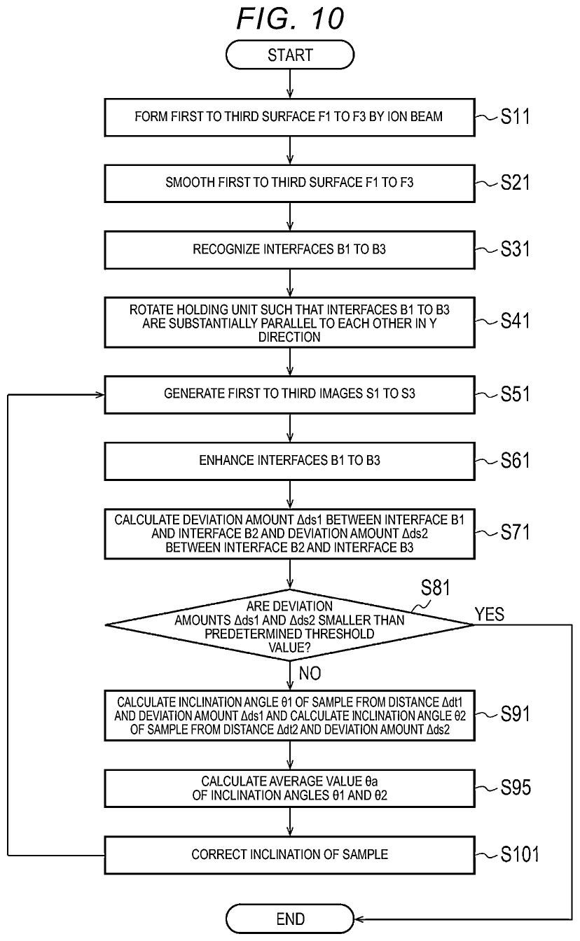

FIG. 10 is a flowchart showing an example of a control method of the charged particle beam apparatus according to the second embodiment.

First, the sample 5 is attached to the holding unit 6 and disposed in the chamber 1.

The FIB irradiation unit 2 irradiates the sample 5 with an ion beam to process the sample 5 into a step shape to form the first surface to the third surface F1 to F3 (S11). The FIB irradiation unit 2 cuts the sample 5 by irradiating the sample 5 with the ion beam from the X direction and moving the emitted ion beam in at least a Y direction. Alternatively, the FIB irradiation unit 2 may cut the sample 5 by irradiating the sample 5 with an ion beam from the X direction and moving the emitted ion beam in the Y direction and the Z direction. When forming the first surface F1, the sample 5 may be cut so that the first surface F1 is flat with respect to the X-Y plane, and thus a recess amount of the sample 5 in the Z direction may be small. On the other hand, when forming the second and third surfaces F2 and F3, it is necessary to increase the distance Δdt1 between the first surface F1 and the second surface F2 and the distance Δdt2 between the second surface F2 and the third surface F3 to some extent in order to increase the deviation amounts Δds1 and Δds2. Therefore, the recess amount (Δdt1) of the second surface F2 in the Z direction with respect to the first surface F1 is preferably larger than the recess amount of the sample 5 in the Z direction. In addition, it is preferable that the recess amount (Δdt2) of the third surface F3 in the Z direction with respect to the second surface F2 is larger than the recess amount of the sample 5 in the Z direction.

Next, the first to third surfaces F1 to F3 are thinly shaved with an ion beam to smooth the first to third surfaces F1 to F3, which are the imaging surfaces of the sample 5 (S21).

Next, the image processing unit 8 generates the images of the first to third surfaces F1 to F3, and recognizes the interfaces B1 to B3 of the sample 5 shown in FIG. 9C (S31). Further, the image processing unit 8 may emphasize the interfaces B1 to B3.

Next, the control arithmetic unit 9 controls the driving unit 7 to rotate the holding unit 6 such that the interfaces B1 to B3 are substantially parallel to each other in the Y direction (S41).

Next, the EB irradiation unit 3 irradiates the first to third surfaces F1 to F3 of the sample 5 with the electron beam, and the detection unit 4 detects the secondary electrons from the sample 5. The image processing unit 8 generates the first to third images S1 to S3 from the detected secondary electrons (S51). The EB irradiation unit 3 may simultaneously irradiate the first to third surfaces F1 to F3 of the sample 5 with the electron beam, and the detection unit 4 may detect the secondary electrons from the sample 5 at once. In this case, the image processing unit 8 may simultaneously obtain the first to third images S1 to S3 with one irradiation of the electron beam. On the other hand, the first to third surfaces F1 to F3 may be separately irradiated with the electron beam by changing the focus of the electron beam. In this case, the image processing unit 8 combines the first to third images S1 to S3 from the separately detected secondary electrons by the detection unit 4 to obtain a composite image. The EB irradiation unit 3 adapts the focus of the electron beam to each of the first to third surfaces F1 to F3. As a result, it is possible for the detection unit 4 and the image processing unit 8 to capture the first to third images S1 to S3 at different timings, respectively. Therefore, the first to third images S1 to S3 are images in which the first to third surfaces F1 to F3 are in focus. That is, the composite image is an image in which the first to third surfaces F1 to F3 are in focus.

Further, the image processing unit 8 enhances the interfaces B1 to B3 by the image processing of the first to third images S1 to S3 or the composite image (S61). For example, the interface B1 is enhanced by using the first image S1. The image processing unit 8 performs contrast enhancement processing on the first image S1. First, the area surrounding the interface B1 is extracted from the first image S1 to generate an extracted image, and then a luminance histogram is created for each pixel using the extracted image. Finally, the obtained histograms are averaged to enhance the contrast of the interface B1. The interface B2 and the interface B3 may also be enhanced in the same manner as the interface B1.

Next, the control arithmetic unit 9 calculates the deviation amount Δds1 between the interface B1 and the interface B2 from the first to third images S1 to S3 or the composite image, and calculates the deviation amount Δds2 between the interface B2 and the interface B3 (S71).

Next, the control arithmetic unit 9 compares the deviation amounts Δds1 and Δds2 with a predetermined threshold value (S81). When any one of the deviation amounts Δds1 and Δds2 is equal to or greater than the predetermined threshold value (NO in S81), the control arithmetic unit 9 calculates the inclination angle θ1 of the sample 5 by performing the calculation of Expression 1 from the distance Δdt1 between the first surface F1 and the second surface F2, which is input in advance, and the deviation amount Δds1. Further, the control arithmetic unit 9 calculates the inclination angle θ2 of the sample 5 by performing the calculation of Expression 1 from the distance Δdt2 between the second surface F2 and the third surface F3, which are input in advance, and the deviation amount Δds2 (S91).

Next, the control arithmetic unit 9 calculates the average value θa of the inclination angles θ1 and θ2 (S95).

Next, in order to bring the average value θa of the inclination angles θ1 and θ2 close to zero, the control arithmetic unit 9 performs feedback control of the driving unit 7 and the holding unit 6 to correct the inclination of the sample 5 in the Z direction (S101).

The control arithmetic unit 9 repeats steps S51 to S101 after the inclination of the sample 5 in the Z direction is corrected. That is, the control arithmetic unit 9 repeats the calculation of the average value θa and the control of the holding unit 6 until both the deviation amounts Δds1 and Δds2 become smaller than the predetermined threshold value.

When both the deviation amounts Δds1 and Δds2 are smaller than the predetermined threshold value (YES in S81), the control arithmetic unit 9 ends the adjustment of the inclination angles θ1 and θ2.

As described above, the charged particle beam apparatus 100 according to the second embodiment calculates the plurality of inclination angles θ1 and θ2 based on the deviation amount Δds1 between the interfaces B1 and B2 in each of the first to third images S1 to S3 of the first to third surfaces F1 to F3 of the sample 5 and the deviation amount Δds2 between the interfaces B2 and B3. In addition, the charged particle beam apparatus 100 may automatically correct the inclination of the sample 5 in the Z direction by using the average value θa of the plurality of inclination angles θ1 and θ2. In the second embodiment, by correcting the inclination of the sample 5 with respect to the Z direction by the average value θa of the plurality of inclination angles θ1 and θ2, the inclination angle with respect to the Z direction can be calculated with higher accuracy.

Other operations of the second embodiment may be the same as the operations of the first embodiment. Therefore, in the second embodiment, the same effects as those of the first embodiment can be obtained.

The control arithmetic unit 9 may calculate the third inclination angle θ3 from Expression 1 based on the third deviation amount Δds3 of each of the interfaces B1 and B3 in the first image S1 and the third image S3, and the third distance Δdt3 from the first surface F1 to the third surface F3 (Δds3=Δds1+Δds2). The control arithmetic unit 9 may further use the inclination angle θ3 obtained in this manner to calculate the average value θa. In this case, for example, the average value θa may be an average of the inclination angles θ1, θ2, and θ3, an average of the inclination angles θ1 and θ3, or an average of the inclination angles θ2 and θ3.

### Modification Example

In the above-described embodiment, the interfaces B1 to B3 are interfaces between any two layers provided in the sample 5. Specifically, for example, the interfaces B1 to B3 may be interfaces between two insulating films having different compositions, which are formed on the stacked body 20, or interfaces between the conductive film (for example, the metal film) and the insulating film. In addition, the interfaces B1 to B3 may be interfaces between the substrate SUB and the stacked body 20, or interfaces between the stacked body 20 and the interlayer insulating film thereon. In addition, the interfaces B1 to B3 may be interfaces between any electrode film and the insulating film in the stacked body 20.

### Third Embodiment

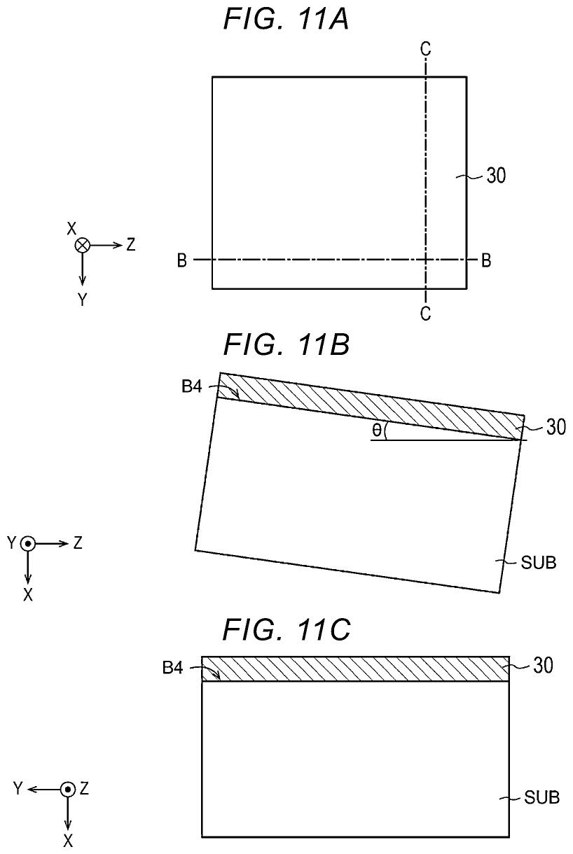

FIGS. 11A to 13C are diagrams showing a state of processing of the sample 5 according to the third embodiment. FIGS. 11A, 12A, and 13A are plan views of the sample 5. FIGS. 11B, 12B, and 13B are cross-sectional views taken along the line B-B of FIGS. 11A, 12A, and 13A, respectively. FIGS. 11C, 12C, and 13C are cross-sectional views taken along the line C-C of FIGS. 11A, 12A, and 13A, respectively.

In the third embodiment, the sample 5 may include, for example, a bulk silicon substrate, a ceramic substrate, or a metal plate. In a case of the bulk substrate, since the stacked film is not provided, there is no interface serving as a reference plane for the inclination of the sample 5 in the Z direction. In such a case, the protective film 30 may be formed on the sample 5, and the interface B4 between the protective film 30 and the sample 5 may be used as the reference plane. That is, the protective film 30 may be deposited on the substrate SUB which is a processed material, and an interface B4 between the protective film 30 and the substrate SUB may be used as the reference plane. The protective film 30 is stacked on the surface of the sample 5 as a pretreatment before the sample 5 is mounted on the charged particle beam apparatus 100. In this case, as a method of stacking the protective film 30 on the surface of the sample 5, carbon thermal vapor deposition or sputtering vapor deposition of gold, platinum, or the like may be used. In this case, the material of the protective film 30 is a carbon film or a metal film such as a gold film and a platinum film. The material of the protective film 30 may be any material different from the sample 5.

For example, as shown in FIGS. 11A to 11C, the protective film 30 is deposited on the surface of the substrate SUB of the sample 5. As the protective film 30, for example, a carbon film or a metal film such as gold and platinum is used.

As shown in FIG. 11B, the interface B4 between the substrate SUB and the protective film 30 is inclined at an inclination angle θ with respect to the Z direction.

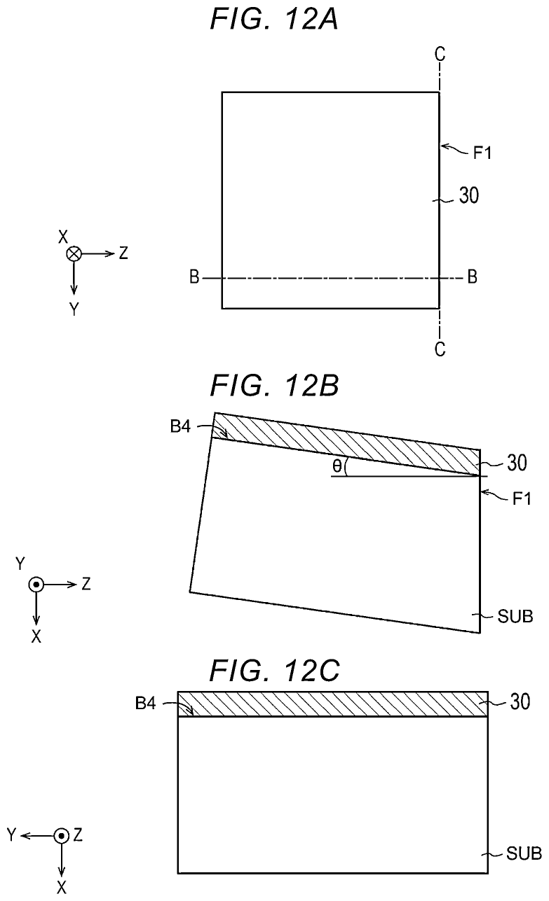

As shown in FIGS. 12A to 12C, the FIB irradiation unit 2 irradiates a part of the sample 5 with an ion beam to process the sample 5. The FIB irradiation unit 2 cuts the sample 5 by irradiating the sample 5 with the ion beam from the X direction and moving the emitted ion beam in at least a Y direction. Alternatively, the FIB irradiation unit 2 may cut the sample 5 by irradiating the sample 5 with an ion beam from the X direction and moving the emitted ion beam in the Y direction and the Z direction. As a result, as shown in FIG. 12B, the sample 5 is processed to have a cut surface (first surface F1) that is substantially parallel to the X-Y plane.

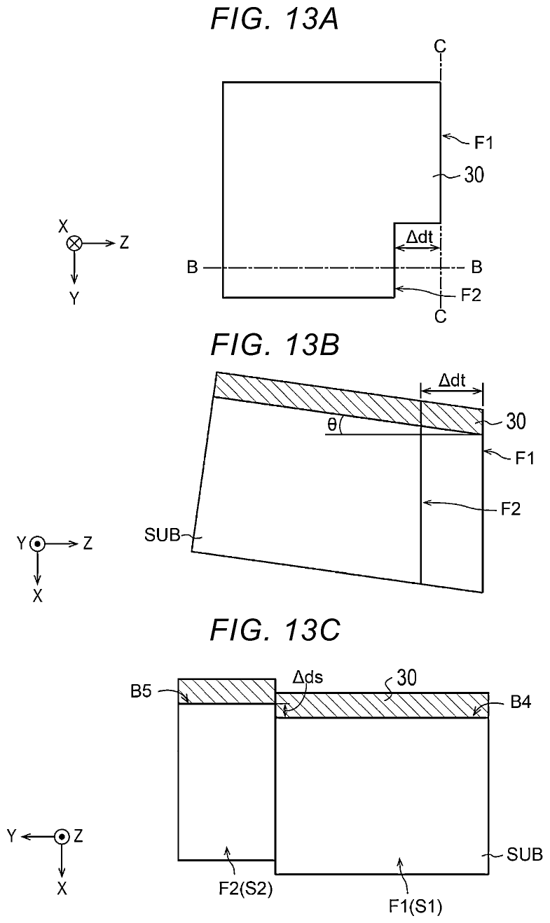

Next, as shown in FIGS. 13A to 13C, the FIB irradiation unit 2 irradiates a part of the sample 5 with the ion beam to process the sample 5. The FIB irradiation unit 2 cuts the sample 5 by irradiating the sample 5 with the ion beam from the X direction and moving the emitted ion beam in at least a Y direction. Alternatively, the FIB irradiation unit 2 may cut the sample 5 by irradiating the sample 5 with an ion beam from the X direction and moving the emitted ion beam in the Y direction and the Z direction. In this case, as shown in FIG. 13A, the ion beam cuts a part of the first surface F1 of the sample 5 to process the sample 5 such that the second surface F2 has a step shape. As a result, as shown in FIG. 13B, the sample 5 is further processed to have a second surface F2 that is substantially parallel to the X-Y plane.

Here, since the sample 5 is inclined at the inclination angle θ with respect to the Z direction, as shown in FIG. 13C, the first surface F1 and the second surface F2 are deviated from each other in the X direction (height direction). That is, the first image and the second image S1 and S2 obtained by irradiating the first and second surfaces F1 and F2 of the sample 5 with the electron beam from the EB irradiation unit 3 are also deviated in the X direction (height direction). The interface B4 between the substrate SUB and the protective film 30 formed thereon in the first image S1 and the interface B5 between the substrate SUB and the protective film 30 formed thereon in the second image S2 are deviated from each other in the X direction by the deviation amount Δds. That is, the interface B4 between the sample 5 and the material film formed thereon in the first image S1 and the interface B5 between the sample 5 and the material film formed thereon in the second image S2 are deviated from each other in the X direction by the deviation amount Δds.

The control arithmetic unit 9 calculates the inclination angles θ of the interfaces B1 and B2 with respect to the Z direction based on the distance Δdt between the first surface F1 and the second surface F2 and the deviation amount Δds in the X direction between the interface B1 of the first surface F1 and the interface B2 of the second surface F2 by using the principle of the triangulation. The control arithmetic unit 9 may calculate the inclination angle θ using, for example, Expression 1, as in the first embodiment.

The configuration of the charged particle beam apparatus 100 according to the third embodiment may be the same as the configuration of the first embodiment. In addition, the operation of the charged particle beam apparatus 100 according to the third embodiment may be the same as the operation of the first embodiment.

In the charged particle beam apparatus 100 according to the third embodiment, the bulk substrate having no interface such as a stacked film can also automatically correct the inclination angle θ. In addition, the third embodiment can obtain the same effects as those of the first embodiment.

While certain embodiments have been described, these embodiments have been presented by way of example only, and are not intended to limit the scope of the disclosure. Indeed, the novel embodiments described herein may be embodied in a variety of other forms; furthermore, various omissions, substitutions, and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A charged particle beam apparatus comprising:
a holding structure for a sample having a reference plane, the holding structure being rotatable to change an angle of the sample with respect to at least a first direction;
a first irradiation device that is configured to process the sample to have a first surface intersecting the reference plane and a second surface separated from the first surface in the first direction by a first distance by irradiating the sample with first charged particles from a second direction;
a second irradiation device that is configured to irradiate the first surface and the second surface with second charged particles from the first direction;
a detector that is configured to detect third charged particles from the first surface and the second surface that have been irradiated with the second charged particles;
an image processing circuit that is configured to generate a first image of the first surface and a second image of the second surface based on the detected third charged particles; and
a processor that is configured to calculate an inclination angle of the reference plane with respect to the first direction based on (i) a first deviation amount in the second direction of the reference plane between the first image and the second image, and (ii) the first distance, and generate a control signal for rotating the holding structure based on the inclination angle.

2. The charged particle beam apparatus according to claim 1, wherein
the first direction and the second direction are substantially orthogonal to each other, and
the processor calculates an inverse tangent of: the first deviation amount of the reference plane divided by the first distance, as the inclination angle.

3. The charged particle beam apparatus according to claim 1, wherein
the image processing circuit generates a composite image obtained by combining the first image and the second image obtained by separately irradiating the first surface and the second surface by the second irradiation device, and separately detecting the third charged particles from the first surface and the second surface, and
the first deviation amount is determined from the composite image.

4. The charged particle beam apparatus according to claim 3, wherein the second irradiation device is separately focused during irradiation of each of the first surface and the second surface.

5. The charged particle beam apparatus according to claim 1, wherein
after the holding structure has been rotated in response to the control signal, the processor repeats the calculation of the inclination angle and the generation of the control signal until the first deviation amount becomes smaller than a threshold value.

6. The charged particle beam apparatus according to claim 1, wherein the first surface and the second surface are substantially parallel to each other.

7. A charged particle beam apparatus comprising:
a holding structure for a sample having a reference plane, the holding structure being rotatable to change an angle of the sample with respect to at least a first direction;
a first irradiation device that is configured to process the sample to have a first surface intersecting with the reference plane, a second surface separated from the first surface by a first distance in the first direction, and a third surface separated from the second surface by a second distance in the first direction by irradiating the sample with first charged particles from a second direction;
a second irradiation device that is configured to irradiate the first surface and the second surface with second charged particles from the first direction;
a detector that is configured to detect third charged particles from the first surface, the second surface, and the third surface that have been irradiated with the second charged particles;
an image processing circuit that is configured to generate a first image of the first surface, a second image of the second surface, and a third image of the third surface based on the detected third charged particles; and
a processor that is configured to
calculate a first inclination angle of the reference plane with respect to the first direction based on (i) a first deviation amount in the second direction of the reference plane in the first image and the second image, and (ii) the first distance,
calculate a second inclination angle of the reference plane with respect to the first direction based on (i) a second deviation amount in the second direction of the reference plane in the second image and the third image, and (ii) the second distance, and
calculate an average value of the first inclination angle and the second inclination angle and generate a control signal for rotating the holding structure based on the average value.

8. The charged particle beam apparatus according to claim 7, wherein
the first direction and the second direction are substantially orthogonal to each other, and
the processor calculates an inverse tangent of: the first deviation amount of the reference plane divided by the first distance, as the first inclination angle, and an inverse tangent of: the second deviation amount of the reference plane divided by the second distance, as the second inclination angle.

9. The charged particle beam apparatus according to claim 7, wherein
the image processing circuit generates a composite image obtained by combining the first image, the second image, and the third image obtained by separately irradiating the first surface, the second surface, and the third surface by the second irradiation device, and separately detecting the third charged particles from the first surface, the second surface, and the third surface, and
the first and second deviation amounts are determined from the composite image.

10. The charged particle beam apparatus according to claim 9, wherein the second irradiation device is separately focused during irradiation of each of the first surface, the second surface, and third surface.

11. The charged particle beam apparatus according to claim 7, wherein
after the holding structure has been rotated in response to the control signal, the processor repeats the calculation of the average value and the generation of the control signal until the first deviation amount and the second deviation amount each becomes smaller than a threshold value.

12. The charged particle beam apparatus according to claim 7, wherein the first surface, the second surface, and the third surface are substantially parallel to each other.

13. A control method for a charged particle beam apparatus including a holding structure for a sample that is rotatable to change an angle of the sample with respect to at least a first direction, the control method comprising:
processing the sample by irradiating the sample with first charged particles in a second direction;
irradiating the sample with second charged particles in the first direction;
detecting third charged particles from the sample that has been irradiated with the second charged particles;
acquiring a first image based on the third charged particles detected from a first surface of the sample;
acquiring a second image formed based on the third charged particles detected from a second surface of the sample, which is separated from the first surface by a first distance in the first direction;
calculating a first inclination angle of a reference plane of the sample with respect to the first direction based on (i) a first deviation amount in the second direction of the reference plane in the first image and the second image, and (ii) the first distance; and
generating a control signal for the holding structure based on the first inclination angle.

14. The control method according to claim 13, further comprising:
acquiring a third image based on the third charged particles detected from a third surface of the sample, which is separated from the second surface by a second distance in the first direction; and
calculating a second inclination angle of the reference plane with respect to the first direction based on (i) a second deviation amount in the second direction of the reference plane in the second image and the third image, and (ii) the second distance, wherein
the control signal for the holding structure is generated based on an average of the first inclination angle and the second inclination angle.

15. The control method according to claim 13, wherein
the first direction and the second direction are substantially orthogonal to each other, and
the first inclination angle is calculated as an inverse tangent of: the first deviation amount of the reference plane divided by the first distance.

16. The control method according to claim 13, wherein
the first surface and the second surface are separately irradiated by the second irradiation device.

17. The control method according to claim 16, further comprising:
separately focusing the second irradiation device during irradiation of each of the first surface and the second surface.

18. The control method according to claim 13, further comprising:
rotating the holding structure in response to the control signal; and
repeating the steps to calculate the first inclination angle and to generate the control signal based on the first inclination angle until the first deviation amount becomes smaller than a threshold value.

19. The control method according to claim 13, further comprising:
preparing a sample having a substrate on which a plurality of insulating layers and a plurality of conductive layers are alternately stacked on the substrate in the first direction.

20. The control method according to claim 13, further comprising:
depositing a protective film on the sample prior to processing the sample, wherein
an interface between the protective film and the sample is the reference plane of the sample.
